(19) United States
(12) Patent Application Publication
(10) Pub. No.: US 2025/0377412 A1
(43) Pub. Date: Dec. 11, 2025

(54) SYSTEM AND METHODS FOR DETERMINING A STATUS OF A BATTERY PACK OF A VEHICLE

(71) Applicant: Cox Automotive, Inc., Atlanta, GA (US)

(72) Inventors: Connor Benjamin Taylor, Norman, OK (US); Sarah Hake, Atlanta, GA (US); Austin Lee, Atlanta, GA (US); David Keith Howland, Yukon, OK (US)

(21) Appl. No.: 18/736,738

(22) Filed: Jun. 7, 2024

(51) Int. Cl. G01R 31/392; G01R 31/367; G01R 31/389; H01M 10/44; H02J 7/00; B60L 53/60

(52) U.S. Cl. CPC G01R 31/392; G01R 31/367; G01R 31/389; H01M 10/443; H02J 7/005; B60L 53/60; H01M 2220/20

(57) ABSTRACT

Methods and systems for determining a status of a battery pack of a vehicle is provided. Charging of the battery pack is initiated. Charging parameters of the battery pack are measured during charging of the battery pack are received. Discharging of the battery pack is initiated. Discharging parameters of the battery pack measured during discharging of the battery pack are received. The status of the battery pack is determined based on the charging parameters and the discharging parameters.

### BACKGROUND

Environmental impact of non-renewable energy sources such as coal, petroleum, natural gas, and the like has led to an increased popularity of electric vehicles and hybrid-electric vehicles among the general population. Electric and hybrid-electric vehicles employ electrochemical devices, for example, a rechargeable battery to power itself. These rechargeable batteries are subject to degradation based on the usage and elemental exposure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the invention and are not intended to be limiting.

FIG. 1 is a diagram of a portion of a vehicle.

FIG. 2 is a diagram illustrating battery modules of a battery pack.

FIG. 3 is a diagram illustrating sections of a battery pack.

FIG. 4 is a diagram illustrating a system for determining a status of a battery pack.

FIG. 5 is a flow diagram of a method of determining a status of a battery pack.

FIG. 6 is a block diagram of a computing device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The disclosure provides systems and methods for determining a status of a battery pack of a vehicle. A battery pack of a vehicle is a rechargeable battery that can be charged, discharged into a load, and recharged many times. With multiple charge/discharge cycle and other environmental factors, a health of a battery pack of a vehicle may degrade over time. Since, a battery pack is an important and one of the most expensive parts of a vehicle, one may need to determine a status of the battery pack to determine an overall health or value of the vehicle. Disclosed techniques provide methods and systems for determining a status of a battery pack of a vehicle.

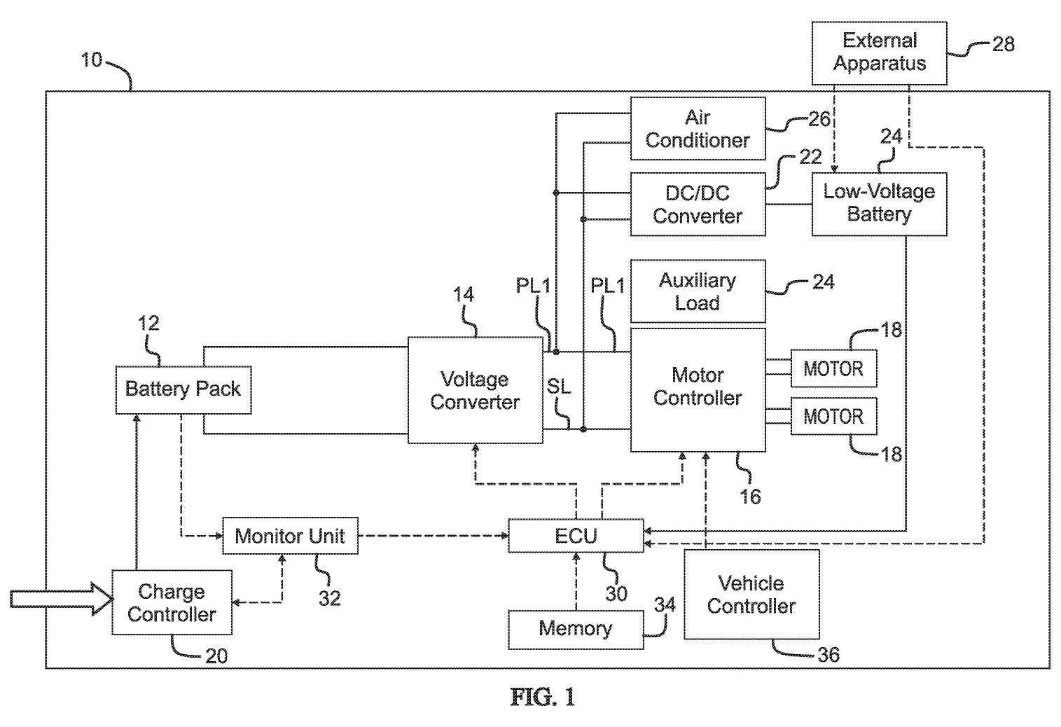

FIG. 1 is a block diagram of a portion of an example vehicle 10. Vehicle 10 can be an electric vehicle or a hybrid vehicle. An electric vehicle is all electrically powered while a hybrid vehicle is powered by both an electric motor and an internal combustion engine. In FIG. 1, an arrow indicated by a solid line represents a direction of a power supply and an arrow indicated by a dotted line represents a direction of a signal transmission.

As shown in FIG. 1, vehicle 10 includes a battery pack 12, a voltage convertor 14, a motor controller 16, motors 18, a charge controller 20, a DC/DC convertor 22, a low-voltage battery 24, an air-conditioner 26, an auxiliary load 28, an Electronic Control Unit (ECU) 30, a monitor unit 32, a memory 34, and a vehicle controller 36. Those skill in the art will understand that vehicle 10 can include fewer or greater number of parts than those listed herein,

Vehicle 10 further includes a power source line PL1 and a ground line SL. Battery pack 12 is connected to voltage convertor 14 (also referred to as a power convertor). Voltage convertor 14 converts the DC voltage provided by battery pack 12 to a voltage level of motors 18. Motor’s 18 shaft torque is transferred to wheels of vehicle 10 through a mechanical transmission mechanism (not shown). In some examples, vehicle 10 can include another voltage convertor to change the DC voltage of battery pack 12 into an AC voltage if motors 18 are AC motors. Thus, motors 18 receive the electrical power from battery pack 12 at proper voltage and current level and transform it into mechanical power to propel vehicle 10.

Vehicle controller 36 is associated with a break and an accelerator pedals of vehicle 10. Vehicle controller sends a control signal to motor controller 16 based on a command from the break and accelerator pedals of vehicle 10. Motor controller 16 can increase the speed or decrease the speed of vehicle 10 based on the command from vehicle controller 36. Motor controller 16 and voltage converter 14 may also charge battery pack 14 during breaking action of vehicle 10 through regenerative power.

DC/DC convertor 22 and air conditioner 26 are connected in parallel between the power source line PL1 and the ground line SL. DC/DC converter 22 drops the voltage supplied by battery pack 12 to charge low-voltage battery 24 or to supply the power to auxiliary load 28. Auxiliary load 28 may include an electronic device such as a lamp and an audio for the vehicle, not shown. In some examples, DC/DC convertor 22 is directly connected to battery pack 12.

ECU 30 may be a Central Processing Unit (CPU) or a Micro-Processing Unit (MPU), and may include an Application Specific Integrated Circuit (ASIC) that performs, based on circuital operation, at least part of processing executed in the CPU or the like. In this embodiment, ECU 30 starts up by receiving the power supply from low voltage battery 24.

Charge controller 20 may controller charging of battery pack 12. For example, charge controller 20 may include a charge port where a charging cable may be plugged to charge battery pack 12. In some examples, charge controller 20 may be part of monitor unit 32. Monitor unit 32 obtains the information about the voltage, current, and temperature of battery pack 12. Monitor unit 32 may be formed as a unit integral with battery pack 12 or monitor unit 32 can be a stand-alone unit. The voltage value obtained by monitor unit 32 may be the voltage value of each battery module and cell. The temperature of battery pack 12 may be obtained through a thermistor, not shown.

Memory 34 stores the information about vehicle 10 and battery pack 12. For example, memory 34 may store a voltage rating, a current rating, a temperature rating, a control upper limit value and a control lower limit value of an electric storage amount for use in charge and discharge control of battery pack 12. Memory 34 may also store performance history of both battery pack 12 and vehicle 10.

ECU 30 performs control such that the electric storage amount in battery pack 12 is maintained within a control range defined by the control upper limit value and the control lower limit value. For example, ECU 30 suppresses charge when the electric storage amount in battery pack 12 exceeds the control upper limit value. That is, ECU 30 prohibits the charge and discharge of battery pack 12 when the electric storage amount in battery pack 12 reaches an electric storage amount corresponding to a charge termination voltage higher than the control upper limit value. The state in which battery pack 12 reaches the charge termination voltage or exceeds the charge termination voltage is referred to as an overcharged state.

Similarly, ECU 30 suppresses discharge when the electric storage amount in battery pack 12 falls below the control lower limit value. For example, ECU 30 prohibits the charge and discharge of battery pack 12 when the electric storage amount in battery pack 12 reaches an electric storage amount corresponding to a discharge termination voltage lower than the control lower limit value. The state in which the electric storage amount in battery pack 12 reaches a discharge termination voltage or falls below the discharge termination voltage is referred to as an over-discharged state.

Battery pack 12 is an electrochemical energy storage device, for example, a rechargeable battery. Battery pack 12 stores energy for later consumption. Battery pack 12 may include a plurality of battery modules connected together. In examples, a battery module may be the smallest unit of battery pack 12 without breaking any permanent mechanical systems. In some embodiments, these battery modules may be manufactured for or recovered from one or more battery packs of a vehicle, for example, an electric vehicle.

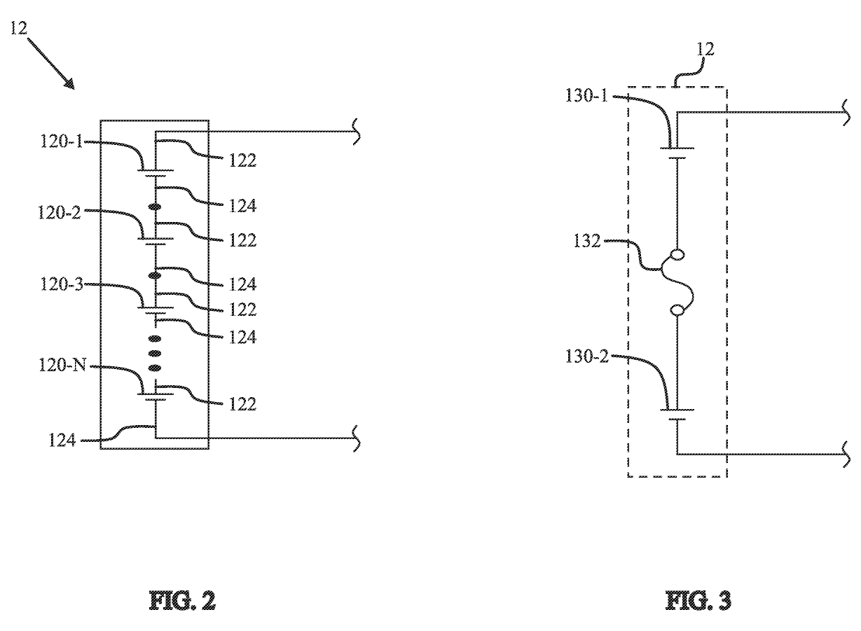

FIG. 2 illustrates an example battery pack 12. As shown in FIG. 2, battery pack 12 may include a plurality of battery modules, for example, a first battery module 120-1, a second battery module 120-2, a third battery module 120-3, …, an Nth battery module 120-N connected together. It may be understood that battery pack 12 may include any number of battery modules. For example, battery pack 12 may include 38, 48, or 56, battery modules.

Each of the plurality of battery modules have a positive terminal 122 and a negative terminal 124. The plurality of battery modules can be combined in a series configuration in which positive terminal 122 of one of the plurality of battery modules is connected to negative terminal 124 of an adjacent battery module. In some arrangement, one or more battery modules are connected in parallel while some battery modules are connected in series. A total capacity and voltage rating of battery pack 12 may depend on a number of battery modules included in battery pack 12 and the connection configuration of the battery modules.

In some examples, one or more fuses may divide battery pack 12 into two or more sections or groupings. Battery sections are generally composed of a plurality of modules and may be structured for ease in disassembly and reconstituted through the use of removable hardware (e.g., threaded rods with removable nuts). These structures may arise for two reasons. First is the requirement for mechanical compression which may be required for proper functioning. Second, intermediate electrical equipment, such as fuses and contactors, are positioned for safety and operation. For example, fuses are typically located mid-battery pack so that removal of the fuse reduces battery voltage by half.

FIG. 3 is a diagram illustrating sections of battery pack 12. As shown in FIG. 3, battery pack 12 includes two sections, a first section 130-1 and a second section 130-2 connected by a fuse 132. Each of first section 130-1 and second section 130-2 may include multiple battery modules, for example, 2, 3, 4, 5, 10, 15, 20, 30, 40, etc. A number of battery modules in each of first section 130-1 and second section 130-2 may be the same or different depending on a design consideration of battery pack 12. In addition, battery pack 12 may include more than two modules and the modules do not have to be separated by fuse 132. Moreover, in some examples, if present, fuse 132 does not have to be between sections, and can be located anywhere along a current path. For example, fuse 132 can be located anywhere on exterior of battery pack 12 so that fuse 132 is more accessible by a user.

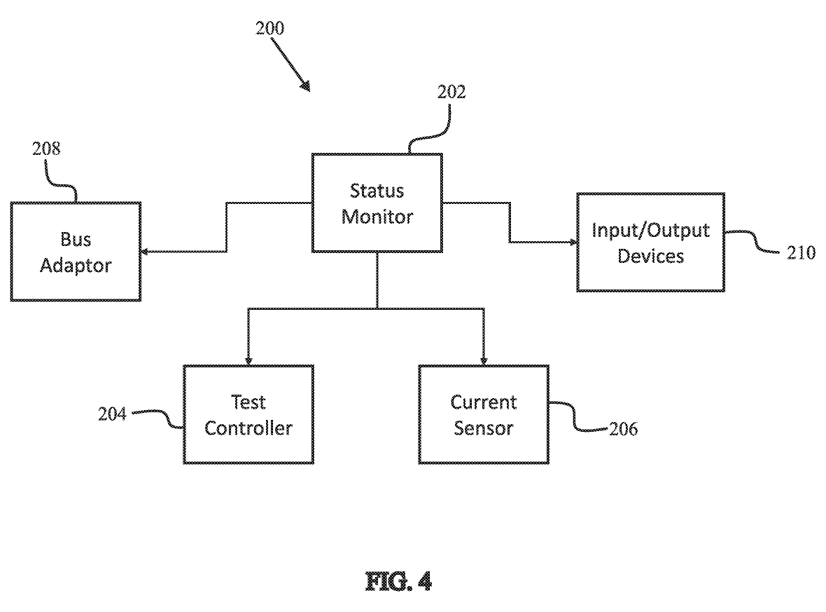

FIG. 4 is a block diagram of a system 200 for determining a status of battery pack 12 of vehicle 10. As shown in FIG. 4, system 200 includes a status monitor 202, a test controller 204, a current sensor 206, a bus adaptor 210, and input/output devices 210. Test controller 204 is connectable between vehicle 10 and a charging station. For example, a charging cable of a charging station is plugged into test controller 204 and then test controller 204 is plugged to a charge port of vehicle 10. Test controller 204 acts as an intermediary to control a charging cycle of battery pack 12. That is, test controller 204 can control a charging and discharging of vehicle 10 and control a current being injected into battery pack 12.

Current sensor 206 is plugged on vehicle 10 such that it can measure amount of current being fed into or drawn from battery pack 12. In some examples, current sensor 206 is a mid-pack fuse that is connected to a current sensor of battery pack 12. Current sensor 206 is operable to determine current flowing in/out of battery pack 12 at a predetermined interval. In some examples, the predetermined interval for current sensor 206 is shorter than a measuring interval associated with an onboard current sensor of vehicle 10. In addition, current sensor 206 has a better accuracy than that of the onboard current sensor of vehicle 10.

Bus adaptor 208 is plugged into ECU 30 of vehicle 10. Through bus adaptor 208, status monitor 202 can communicated with ECU and can receive battery parameters of battery pack 12 as measured by monitor unit 32 and ECU 30. Battery parameters may include one or more of a rating of battery pack 12, a status of charge, a current voltage level, a rate of charge, a rate of discharge, a current temperature, historical data associated with charge/discharge, battery health, etc. Rating of battery pack 12 may include a maximum current rating, a maximum charge rating, a minimum charge rating, etc.

Input/output devices 210 are used to provide information about vehicle 10. For example, input/output devices 210 may include a scanner to scan a Vehicle Identification Number (VIN) of vehicle 10 and to scan an identifier of battery pack 12. In some other examples, input/output devices 210 may include a keyboard, a mouse, a microphone, and camera to capture information associated with vehicle 10 and battery pack 12. Input/output devices 210 may further include a display device.

To initiate status determination, a user may scan a VIN barcode of vehicle 10 using a scanner. Status monitor 202 may determine details of vehicle 10 based on the scanned VIN. For example, status monitor 202 may determine a make and model of vehicle 10 and instruction manuals associated with vehicle 10. In addition, status monitor 202 may determine a charger type and instructions on how to plug a charging cable to a charge port of vehicle 10. Status monitor 202 may then display, on a display device, instructions for a user to plug in test controller 204 to the charging cable and then to plug test controller 204 to the charge port of vehicle 10. In addition, status monitor 202 may then display, on the display device, instructions for the user to plug in current sensor 206 and bus adaptor 208 to vehicle 10. Once the user has plugged in test controller 204, current sensor 206, and bus adaptor 208, the user can provide a confirmation of the same through one of input/output devices 210. After receiving the confirmation, status monitor 202 may determine a status of battery pack 12 of vehicle 10.

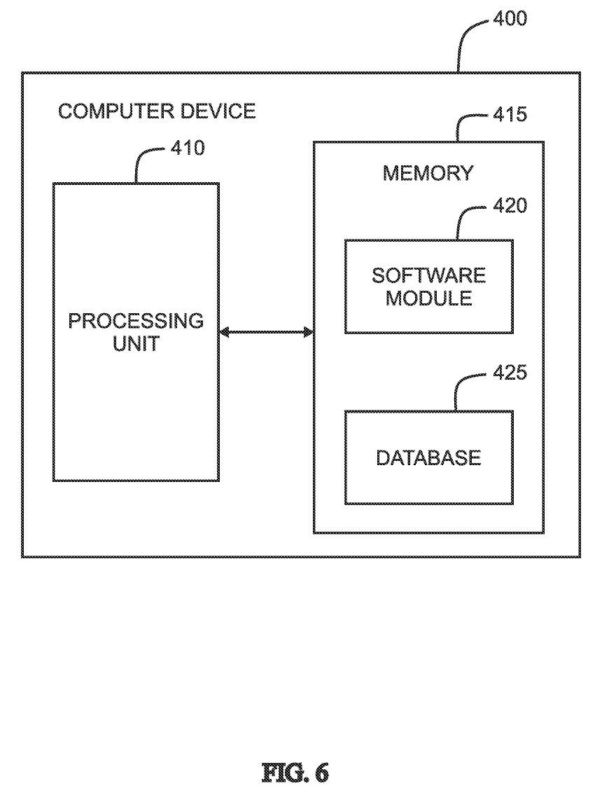

The elements described above of vehicle 10 and system 200 (e.g., motor controller 16, charge controller 20, ECU 30, monitor unit 32, vehicle controller 36, status monitor 202, and test controller 204) may be practiced in hardware and/or in software (including firmware, resident software, micro-code, etc.) or in any other circuits or systems. The elements of vehicle 10 and system 200 may be practiced in electrical circuits comprising discrete electronic elements, packaged or integrated electronic chips containing logic gates, a circuit utilizing a microprocessor, or on a single chip containing electronic elements or microprocessors. Furthermore, the elements of vehicle 10 and system 200 may also be practiced using other technologies capable of performing logical operations such as, for example, AND, OR, and NOT, including but not limited to, mechanical, optical, fluidic, and quantum technologies. As described in greater detail below with respect to FIG. 6, the elements of vehicle 10 and system 200 may be practiced in a computing device 400.

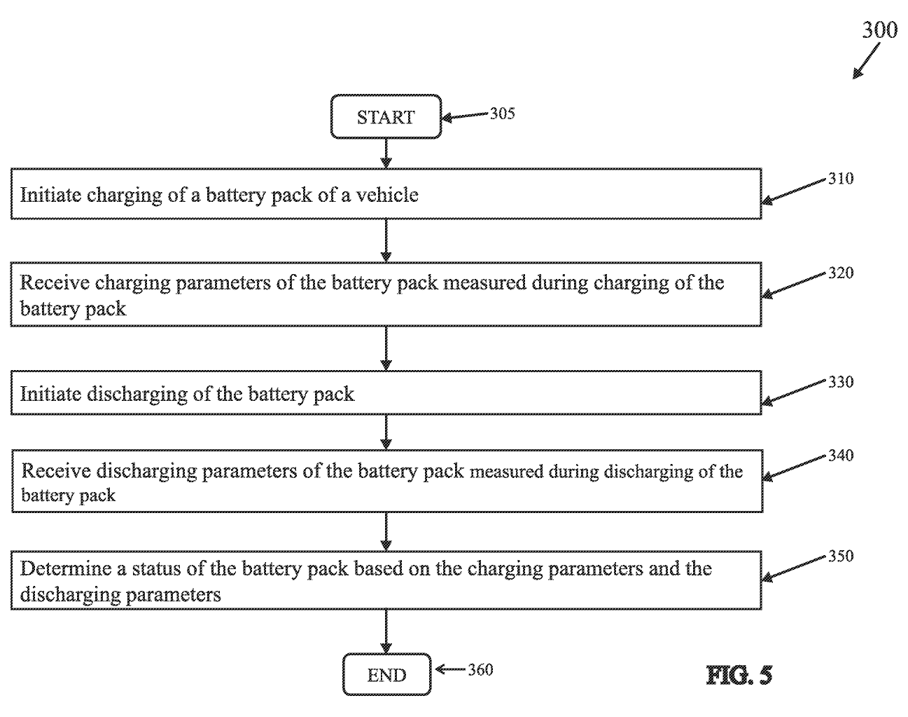

FIG. 5 is a flow chart setting forth the general stages involved in a method 300 consistent with an embodiment of the disclosure for determining a status of battery pack 12 of vehicle 10. Method 300 is being described to be performed by status monitor 202. However, method 300 may be performed by other components of vehicle 10 or system 200. Ways to implement the stages of method 300 will be described in greater detail below.

Method 300 begins at starting block 305 and proceeds to stage 310 where status monitor 202 initiates charging of battery pack 12. For example, status monitor 202 may wirelessly communicate with test controller 204 and initiate charging of battery pack 12. In some examples, test controller 204 includes a circuit interrupter that can be wirelessly controlled by status monitor 202. The circuit interrupter of test controller 204 may be closed to start charging of battery pack 12.

In some examples, before starting charging of battery pack 12, status monitor 202 may instruct a user to change settings of vehicle 10. For example, status monitor 202 may instruct the user to switch off air conditioner 26, a heating unit, and all auxiliary load 24 and disconnect all external apparatus 28. The instructions may be provided through input/output devices 210, for example, a display device. The instructions may include details on how to switch off auxiliary load 24. Once having switched off, the user can provide a confirmation of the same to status monitor 202 through input/output devices 210.

In some example embodiments, status monitor 202 may receive static parameters of battery pack 12. Battery pack 12 may be in static mode when each of auxiliary load 24, air conditioner 26, and a heating unit is switched off and each external apparatus 28 is disconnected. The static parameters may include a state of charge, a temperature, a current (if any), voltage across terminals, etc. Once having received the static parameters, status monitor 202 may initiate charging of battery pack 12 through test controller 204.

After initiating charging of battery pack 12 at stage 310, method 300 proceeds to stage 320 where status monitor 202 receives charging parameters of battery pack 12 measured charging of battery pack 12. During charging, status monitor 202 may receive charging parameters from test controller 204, current sensor 206, and ECU 30. For example, for each predetermined interval, status monitor 202 may receive a state of charge, a voltage, a current, a temperature, etc. The state of charge, the voltage, and the temperature measurements may be received from ECU 30. The current measurements may be received from both current sensor 30 and ECU 30. Current sensor 30 is operable to measure current flowing through battery pack 12 at a predetermined frequency. Similarly, sensors associated with ECU 30 and monitor unit 32 are operable to measure a state of charge, a voltage, a current, a temperature, etc. of battery pack 12 at a predetermined frequency. After receiving the charging parameters for a predetermined charging period, status monitor 202 may discontinue the charging of battery pack 12. For example, status monitor 202 may wirelessly instruct test controller 204 to discontinue the charging of battery pack 12.

Once having received the charging parameters of battery pack 12 at stage 320, method 300 may proceed to stage 330 where status monitor 202 initiates discharging of battery pack 12. During discharging, status monitor 202 may aim to drain maximum possible current out of battery pack 12 using loads associated with vehicle 10. Therefore, and in some embodiments, for discharging, status monitor 202 may determine all possible loads associated with vehicle 10, that is, all air conditioner 26, a heating unit, auxiliary load 24, external apparatus 28, etc. Status monitor 202 may determine an ambient temperature at a location of vehicle 10 and may determine whether to switch on air conditioner 26 or the heating unit of vehicle 10 based on the determined ambient temperature. Status monitor 202 then may provide instructions to the user to switch on air conditioner 26 or the heating unit, auxiliary load 24, and external apparatus 28 to initiate discharging of vehicle 10. The instructions may be provided using input/output devices 210.

After initiating discharging of battery pack 12 at stage 330, method 300 proceeds to stage 340 where monitor unit 202 receives discharging parameters of battery pack 12 measured during discharging of battery pack 12. During discharging, status monitor 202 may receive discharging parameters from current sensor 206 and ECU 30. For example, for each predetermined interval, status monitor 202 may receive a state of charge, a voltage, a current, a temperature, etc. The state of charge, the voltage, and the temperature measurements may be received from ECU 30. The current measurements may be received from both current sensor 30 and ECU 30. After receiving the discharging parameters for a predetermined charging period, status monitor 202 may discontinue discharging of battery pack 12.

Once having received the discharging parameters of battery pack 12 at stage 340, method 300 proceeds to stage 350 where status monitor 202 determines the status of battery pack 12 based on the charging parameters and the discharging parameters. The status may include a health score of battery pack 12 on a predetermined scale, for example, on a 0-1 or a 0-100 scale. For determining the health score, each of the charging parameters and the discharging parameters may be provided an associated weight. The overall health score is determined based on weighted sum of these parameters.

In some examples, other parameters, for example, the static parameters, a maintenance history, a charge/discharge history, etc. may also be included in the health score determination. These other parameters may also be assigned an associated weight for the health score determination. In example embodiments, a user may be able to change or adjust the associated weights for one or more parameters used for determining the health score.

In some examples, an internal impedance or an internal resistance of battery pack 12 is determined based on the voltage and the current measurements received during charging and discharging of battery pack 12. The internal impedance may be determined for each predetermined period for which the voltage and current measurements are received. An average of these multiple determinations may be calculated to determine an overall internal impedance. Ideally, for battery pack 12, the internal impedance is to be closer to zero. A higher than zero internal impedance may indicate battery health degradation. Therefore, and in accordance with example embodiments, the internal impedance is used as a primary factor in the health score determination. For example, the internal impedance may have an associated weight greater than any other parameter for the health score determination. In some examples, a health score is determined for each module or section of battery pack 12. An overall health score of battery pack 12 is then determined based on health scores of each module or section of battery pack 12. After determining the status of battery pack 12 at block 350, method 300 may terminate at block 360.

FIG. 6 shows computing device 400. As shown in FIG. 6, computing device 400 includes a processing unit 410 and a memory unit 415. Memory unit 415 includes a software module 420 and a database 425. While executing on processing unit 410, software module 420 performs, for example, processes for determining a status of battery pack 12, including for example, any one or more of the stages from method 300 described above with respect to FIG. 5. Computing device 400, for example, provides an operating environment for motor controller 16, charge controller 20, ECU 30, monitor unit 32, vehicle controller 36, status monitor 202, test controller 204, etc. Motor controller 16, charge controller 20, ECU 30, monitor unit 32, vehicle controller 36, status monitor 202, test controller 204, etc. may operate in other environments and are not limited to computing device 400.

Computing device 400 can be implemented using a tablet device, a mobile device, a smart phone, a telephone, a remote control device, a personal computer, a network computer, a mainframe, a router, a switch, a server cluster, a smart TV-like device, a network storage device, a network relay device, or other similar microcomputer-based device. Computing device 400 can include any computer operating environment, such as hand-held devices, multiprocessor systems, microprocessor-based or programmable sender electronic devices, minicomputers, mainframe computers, and the like. Computing device 400 can also be practiced in distributed computing environments where tasks are performed by remote processing devices. The aforementioned systems and devices are examples and computing device 400 can comprise other systems or devices.

Embodiments of the disclosure, for example, can be implemented as a computer process (method), a computing system, or as an article of manufacture, such as a computer program product or computer readable media. The computer program product can be a computer storage media readable by a computer system and encoding a computer program of instructions for executing a computer process. The computer program product can also be a propagated signal on a carrier readable by a computing system and encoding a computer program of instructions for executing a computer process. Accordingly, the present disclosure can be embodied in hardware and/or in software (including firmware, resident software, micro-code, etc.). In other words, embodiments of the present disclosure can take the form of a computer program product on a computer-usable or computer-readable storage medium having computer-usable or computer-readable program code embodied in the medium for use by or in connection with an instruction execution system. A computer-usable or computer-readable medium can be any medium that can contain, store, communicate, propagate, or transport the program for use by or in connection with the instruction execution system, apparatus, or device.

The computer-usable or computer-readable medium can be, for example but not limited to, an electronic, magnetic, optical, electromagnetic, infrared, or semiconductor system, apparatus, device, or propagation medium. More specific computer-readable medium examples (a non-exhaustive list), the computer-readable medium can include the following: an electrical connection having one or more wires, a portable computer diskette, a random access memory (RAM), a read-only memory (ROM), an erasable programmable read-only memory (EPROM or Flash memory), an optical fiber, and a portable compact disc read-only memory (CD-ROM). Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory.

While certain embodiments of the disclosure have been described, other embodiments may exist. Furthermore, although embodiments of the present disclosure have been described as being associated with data stored in memory and other storage mediums, data can also be stored on or read from other types of computer-readable media, such as secondary storage devices, like hard disks, or a CD-ROM, a carrier wave from the Internet, or other forms of RAM or ROM. Further, the disclosed methods’ stages may be modified in any manner, including by reordering stages and/or inserting or deleting stages, without departing from the disclosure.

Furthermore, embodiments of the disclosure may be practiced in an electrical circuit comprising discrete electronic elements, packaged or integrated electronic chips containing logic gates, a circuit utilizing a microprocessor, or on a single chip containing electronic elements or microprocessors. Embodiments of the disclosure may also be practiced using other technologies capable of performing logical operations such as, for example, AND, OR, and NOT, including but not limited to, mechanical, optical, fluidic, and quantum technologies. In addition, embodiments of the disclosure may be practiced within a general purpose computer or in any other circuits or systems.

Embodiments of the disclosure may be practiced via a system-on-a-chip (SOC) where each or many of the element illustrated in FIG. 4 may be integrated onto a single integrated circuit. Such a SOC device may include one or more processing units, graphics units, communications units, system virtualization units and various application functionality all of which may be integrated (or “burned”) onto the chip substrate as a single integrated circuit. When operating via a SOC, the functionality described herein with respect to embodiments of the disclosure, may be performed via application-specific logic integrated with other components of computing device 400 on the single integrated circuit (chip).

Embodiments of the present disclosure, for example, are described above with reference to block diagrams and/or operational illustrations of methods, systems, and computer program products according to embodiments of the disclosure. The functions/acts noted in the blocks may occur out of the order as shown in any flowchart. For example, two blocks shown in succession may in fact be executed substantially concurrently or the blocks may sometimes be executed in the reverse order, depending upon the functionality/acts involved.

While the specification includes examples, the disclosure’s scope is indicated by the following claims. Furthermore, while the specification has been described in language specific to structural features and/or methodological acts, the claims are not limited to the features or acts described above. Rather, the specific features and acts described above are disclosed as example for embodiments of the disclosure.

What is claimed is:

1. A method comprising:
initiating charging of a battery pack of a vehicle;
receiving charging parameters of the battery pack measured during charging of the battery pack;
initiating discharging of the battery pack;
receiving discharging parameters of the battery pack measured during discharging of the battery pack; and
determining a status of the battery pack based on the charging parameters and the discharging parameters.

2. The method of claim 1, wherein determining the status of the battery pack comprises determining a health score of the battery pack on a predetermined scale.

3. The method of claim 1, further comprising:
determining an impedance of the battery pack from the charging parameters and the discharging parameters; and
determining the status of the battery pack based on the impedance.

4. The method of claim 1, further comprising:
determining static parameters of the battery pack when the battery pack is neither charging nor discharging; and
determining the status of the battery pack based on the charging parameters, the discharging parameters, and the static parameters.

5. The method of claim 1, further comprising:
assigning an associated weight to each of the charging parameters and each of the discharging parameters; and
determining the status comprising a health score of the battery pack based on the associated weight, the charging parameters, and the discharging parameters.

6. The method of claim 1, wherein the charging parameters and the discharging parameters comprises one or more of the following: a voltage, a current, a state of charge, and a temperature.

7. The method of claim 1, further comprising:
providing instructions to a user to prepare the vehicle for initiating charging and discharging of the battery pack.

8. A status monitor for determining a status of a battery pack of a vehicle, comprising:
a memory device; and
a processing unit connected to the memory device, wherein the processing unit is operative to:
initiate charging of a battery pack of a vehicle;
receive charging parameters of the battery pack measured during charging of the battery pack;
initiate discharging of the battery pack;
receive discharging parameters of the battery pack measured during discharging of the battery pack; and
determine a status of the battery pack based on the charging parameters and the discharging parameters.

9. The status monitor of claim 8, wherein the processing unit being operative to determine the status of the battery pack comprises the processing unit being operative to determine a health score of the battery pack on a predetermined scale.

10. The status monitor of claim 8, wherein the processing unit is further operative to:
determine an impedance of the battery pack based on the charging parameters and the discharging parameters; and
determine the status of the battery pack based on the impedance.

11. The status monitor of claim 8, wherein the processing unit is further operative to:
determine static parameters of the battery pack when the battery pack is neither charging nor discharging; and
determine the status of the battery pack based on the charging parameters, the discharging parameters, and the static parameters.

12. The status detector of claim 8, wherein the processing unit is further operative to:
assign an associated weight to each of the charging parameters and each of the discharging parameters; and
determine the status of the battery pack comprising a health score based on the associated weight, the charging parameters, and the discharging parameters.

13. The status detector of claim 8, wherein the processing unit is further operative to:
provide instructions to a user to prepare the vehicle for charging and discharging of the battery pack.

14. A system for determining a status of a battery pack of a vehicle, the system comprising:
a current sensor connected to the battery pack and operable to measure a current flowing through the battery pack;
a test comptroller connectable between a charging cable and a charge point of the battery pack, wherein the test controller is operable to interrupt connection between the charging cable and the battery pack; and
a status monitor connected to an electronic control unit of the vehicle, wherein the status monitor is operable to:
initiate charging of the battery pack through the test controller;
receive charging parameters of the battery pack measured during charging of the battery pack;
initiate discharging of the battery pack;
receive discharging parameters of the battery pack measured during discharging of the battery pack; and
determine the status of the battery pack based on the charging parameters and the discharging parameters.

15. The system of claim 14, further comprising a scanner, wherein the status monitor is operable to:
receive a scan report of a vehicle identification number of the vehicle from the scanner;
determine, from the vehicle identification number, a make and a model of the vehicle;
determine battery information of the battery pack; and
determine one or more instructions associated with the vehicle.

16. The system of claim 14, further comprising a display device, wherein the status monitor is further operable to: display, on the display device, one or more instructions on plugging the test controller to the charging cable and plugging the test controller to the charge point of the vehicle.

17. The system of claim 14, wherein the status monitor being operable to initiate charging of the battery pack comprises the status monitor being operable to wirelessly communicate with the test controller to connect the charging cable to the charge point.

18. The system of claim 14, wherein the status monitor being operable to initiate charging of the battery pack comprises the status monitor being operable to instruct a user to switch of any auxiliary load and disconnect any external apparatus connected to the vehicle prior to initiating charging of the battery pack.

19. The system of claim 14, wherein the status monitor being operable to initiate discharging of the battery pack comprises the status monitor being operable to instruct a user to switch on each auxiliary load and switch on one of an air conditioner and a heating unit of the vehicle.

20. The system of claim 14, wherein the status monitor being operable to determine the status of the battery pack comprises the status monitor being operable to determine a health score of the battery pack on a predetermined scale.
